(19) United States
(12) Patent Application Publication
(10) Pub. No.: US 2016/0100482 A1
(43) Pub. Date: Apr. 7, 2016

(54) PRINTED WIRING BOARD WITH METAL POST AND METHOD FOR MANUFACTURING THE SAME

(71) Applicant: IBIDEN CO., LTD., Ogaki (JP)

(72) Inventor: Masatoshi Kunieda, Ogaki (JP)

(73) Assignee: IBIDEN CO., LTD., Ogaki (JP)

(21) Appl. No.: 14/874,647

(22) Filed: Oct. 5, 2015

(30) Foreign Application Priority Data
Oct. 3, 2014 (JP) 2014-204504

(51) Int. Cl. H05K 1/11; H05K 3/40; H05K 1/09; H05K 3/46; H05K 3/02; H05K 3/06

(52) U.S. Cl. CPC H05K 1/11; H05K 3/027; H05K 3/062; H05K 1/111; H05K 1/09; H05K 3/4644; H05K 3/4007; H05K 2201/10742

(57) ABSTRACT

A printed wiring board includes a resin insulating layer, a conductor layer formed on the resin insulating layer and including conductor pads, a solder resist layer formed on the resin insulating layer such that the solder resist layer is covering the conductor layer and has opening portions exposing the conductor pads, respectively, and metal posts formed on the conductor pads such that each of the metal posts is protruding from the solder resist layer and has a side surface forming an angle with respect to a surface of the solder resist layer.

### CROSS-REFERENCE TO RELATED APPLICATIONS

The present application is based upon and claims the benefit of priority to Japanese Patent Application No. 2014-204504, filed Oct. 3, 2014, the entire contents of which are incorporated herein by reference.

### BACKGROUND OF THE INVENTION

1. Field of the Invention

The present invention relates to a printed wiring board with a metal post and a method for manufacturing the same.

2. Description of Background Art

Japanese Patent Laid-Open Publication No. 2006-074002 describes a package substrate in which terminals as connecting parts between a package substrate and a semiconductor component are formed by mounting solder balls on conductor pads in openings of a solder resist. The entire contents of this publication are incorporated herein by reference.

### SUMMARY OF THE INVENTION

According to one aspect of the present invention, a printed wiring board includes a resin insulating layer, a conductor layer formed on the resin insulating layer and including conductor pads, a solder resist layer formed on the resin insulating layer such that the solder resist layer is covering the conductor layer and has opening portions exposing the conductor pads, respectively, and metal posts formed on the conductor pads such that each of the metal posts is protruding from the solder resist layer and has a side surface forming an angle with respect to a surface of the solder resist layer.

According to another aspect of the present invention, a method for manufacturing a printed wiring board includes preparing a printed wiring board including a resin insulating layer, and a conductor layer formed on the resin insulating layer and including conductor pads, forming a solder resist layer on the resin insulating layer such that the solder resist layer covers the conductor layer, affixing a resin film having a bonding layer on the solder resist layer, forming opening portions penetrating through the solder resist layer and the resin film such that the opening portions reach the conductor pads, respectively, forming metal posts in the opening portions respectively such that the metal posts connect to the conductor pads, respectively, and peeling off the resin film from the solder resist layer such that each of the metal posts is protruding from the solder resist layer and has a side surface forming an angle with respect to a surface of the solder resist layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an embodiment of a printed wiring board with a metal post of the present invention;

FIG. 2A-2D are cross-sectional views illustrating an embodiment of a method for manufacturing a printed wiring board of the present invention for manufacturing the printed wiring board illustrated in FIG. 1;

FIG. 3 is a cross-sectional view illustrating another embodiment of a printed wiring board with a metal post of the present invention;

FIG. 4 is a cross-sectional view illustrating yet another embodiment of a printed wiring board with a metal post of the present invention;

FIG. 5 is a cross-sectional view illustrating an application example of the printed wiring board with a metal post of an embodiment of the present invention; and

FIG. 6 is a cross-sectional view illustrating another application example of the printed wiring board with a metal post of an embodiment of the present invention.

### DETAILED DESCRIPTION OF THE EMBODIMENTS

The embodiments will now be described with reference to the accompanying drawings, wherein like reference numerals designate corresponding or identical elements throughout the various drawings.

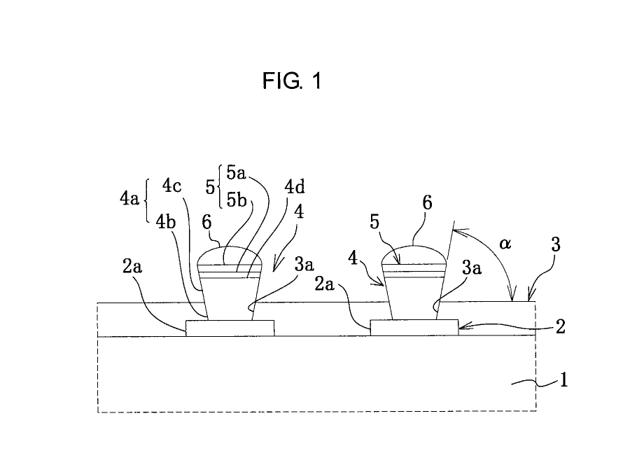

FIG. 1 is a cross-sectional view illustrating an embodiment of a printed wiring board with a metal post of the present invention. The printed wiring board with metal post of the present embodiment includes: a resin insulating layer 1; a conductor layer 2 that is formed in the resin insulating layer 1 and includes conductor pads (2a); a solder resist layer 3 that is formed on the resin insulating layer 1 and on the conductor layer 2 and has openings (3a) that respectively expose at least portions of the conductor pads (2a); and metal posts 4 that are respectively formed on the conductor pads (2a). The metal posts 4 are formed by electroless metal plating and protrude from the solder resist layer 3. On each of the metal posts 4, a solder bump 6 is formed via an intermediate metal layer 5, and a terminal as a connecting part, for example, between a package substrate and a semiconductor component is formed.

A pitch (center-to-center distance) of the metal posts 4 is 30 μm or more and 80 μm or less. As a result, a package substrate can be formed on which, for example, mounted semiconductor components are connected by an ultrahigh density wiring. The electroless metal plating that forms the metal posts 4 is reliably filled in the openings (3a) of the solder resist layer 3 and in openings (7a) of a PET film (to be described later), the openings being finely formed along with a demand for fineness of the terminal pitch. Therefore, the metal posts 4 have uniform heights. Further, the solder bumps 6 are formed on the metal posts 4 that protrude from the solder resist layer 3. Therefore, the terminals are increased in height, and an underfill material for insulation between the terminals and for bonding of a semiconductor component can be easily filled in a gap between a surface of the solder resist layer 3 and the semiconductor component that is connected to the solder bumps 6 on the metal posts 4.

The conductor pads (2a) may be SMD (Solder Mask Defined) type conductor pads or NSMD (Non Solder Mask Defined) type conductor pads. In the case of SMD type conductor pads, as illustrated in the drawings, the conductor pads (2a) are partially exposed from the openings (3a) of the solder resist layer 3. On the other hand, in the case of NSMD type conductor pads, although not illustrated in the drawings, the conductor pads (2a) are entirely exposed from the openings (3a) of the solder resist layer 3.

A side surface (4a) of each of the metal posts 4 has a portion (4b) that is inside the solder resist layer 3 and a portion (4c) that protrudes from the solder resist layer 3. The portions (4b, 4c) mutually smoothly connected and are mutually continuous in an illustration of a cross section perpendicular to a surface of the conductor pad (2a). As a result, there is no projection on the side surface (4a). Therefore, an insulation distance is ensured between the metal posts 4 in an ultrahigh-density wiring.

The portion (4c) of the side surface (4a) of each of the metal posts 4 that protrudes from the solder resist layer 3 forms an angle (α) with respect to the surface of the solder resist layer 3. It is preferable that the angle (α) between the portion (4c) of the side surface (4a) of each of the metal posts 4 that protrudes from the solder resist layer 3 and the surface of the solder resist layer 3 be 45 degrees or more and 90 degrees or less. When the angle (α) is less than 45 degrees, an outer diameter of an upper end part of each of the metal posts 4 becomes too large and an insulation distance between adjacent metal posts 4 is insufficient. When the angle (α) is more than 90 degrees, the outer diameter of the upper end part of each of the metal posts 4 becomes too small and it is possible that a sufficient height of each of the solder bumps 6 cannot be ensured. It is preferable that the angle (α) with respect to the surface of the solder resist layer 3 be less than 90 degrees. An insulation distance against migration can be further increased by increasing a distance between the openings (3a) on the surface of the solder resist layer 3.

The electroless metal plating that forms the metal posts 4 may be electroless copper plating. However, it is preferable that the electroless metal plating be electroless nickel plating. The electroless nickel plating can be formed thicker than the electroless copper plating in a short period of time and thus can be reliably filled in the openings (3a) of the solder resist layer 3 and in the openings (7a) of the PET film. Further, nickel is more migration resistant than copper and thus electrical reliability is increased.

It is preferable that phosphorus content in the electroless nickel plating that forms the metal posts 4 be 5% or more and 12% or less. When the phosphorus content is less than 5%, it is likely to cause reduction in insulation due to migration. When the phosphorus content is more than 12%, adhesion strength of the solder bumps 6 (to be described later) decreases.

Among an upper surface (4d) and the side surface (4a) of each of the metal posts 4, the intermediate metal layer 5 is provided only on the upper surface (4d). As a result, the intermediate metal layer 5 does not protrude from the side surface (4a) and thus an insulation distance between the metal posts 4 is ensured. The solder bumps 6 are respectively formed on the intermediate metal layers 5. It is preferable that the intermediate metal layer 5 be formed by sequentially laminating a palladium layer (5a) and a gold layer (5b). Palladium and gold facilitate formation of a nickel alloy between nickel of the metal posts 4 and solder of the solder bumps 6, and increases the adhesion strength of the solder bumps 6 to the metal posts 4.

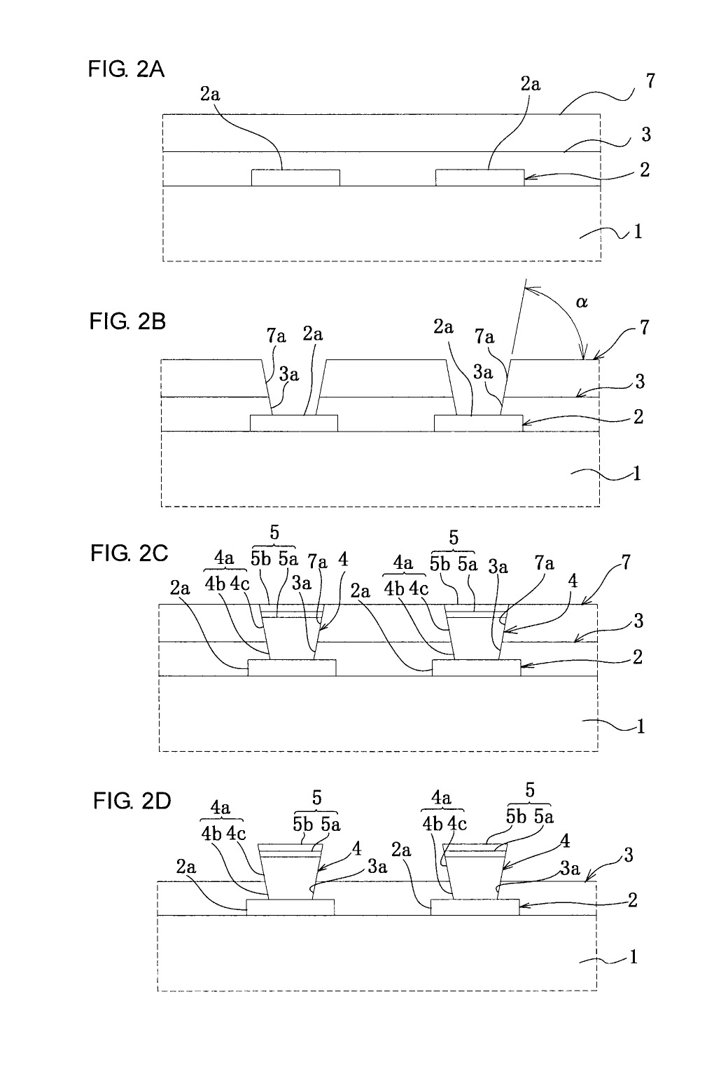

In the following, an embodiment of a method for manufacturing the printed wiring board with a metal post of the present invention is described based on the drawings. FIG. 2A-2D are cross-sectional views illustrating an embodiment of a method for manufacturing the printed wiring board with a metal post of the present invention.

In the method for manufacturing the printed wiring board of the present embodiment, as illustrated in FIG. 2A, an intermediate substrate is prepared that has a resin insulating layer 1 and a conductor layer 2 formed on the resin insulating layer 1. The conductor layer 2 is formed, for example, using an additive method, a semi-additive method, a subtractive method, or the like. The conductor layer 2 is formed of, for example, copper. The conductor layer 2 includes the conductor pads (2a) for mounting an electronic component such as a semiconductor component, and wirings (not illustrated in the drawings) such as a signal line and a power source line.

The solder resist layer 3 is formed on the resin insulating layer 1 and the conductor layer 2. As a resin film with a bonding layer, for example, a PET film 7 with a bonding layer is affixed on the solder resist layer 3. The PET film 7 has a thickness of 7-30 μm, preferably 10-15 μm, which allows the PET film 7 to be easily melted by laser. As illustrated in FIG. 2B, the openings (3a, 7a) that penetrate through the solder resist layer 3 and the PET film 7 to reach the conductor pads (2a) are formed in the solder resist layer 3 and the PET film 7. The openings (3a) of the solder resist layer 3 and the openings (7a) of the PET film 7 are substantially simultaneously formed using the same method and are mutually smoothly connected and mutually continuous. In the present embodiment, the openings (3a) and the openings (7a) are formed using laser, preferably UV laser that is suitable for forming small-diameter holes. By increasing laser output, the solder resist layer 3 is sufficiently melted, and an inner wall surface of each of the openings (3a) is in an inverted truncated cone shape such that the inner wall surface linearly intersects the surface of the conductor pads (2a). By focusing a laser beam, the intersecting angle (α) is set to 45 degrees or more and less than 90 degrees.

As illustrated in FIG. 2B, the metal posts 4 are formed in the openings (3a) of the solder resist layer 3 and in the openings (7a) of the PET film 7 by electroless plating. The metal posts 4 are formed, for example, by electroless nickel plating. The metal posts 4 may also be formed by electroless copper plating. The metal posts 4 may also be formed by electrolytic copper plating.

The side surface (4a) of a metal posts 4 includes the portion (4b) and the portion (4c), the portion (4b) being formed by an opening (3a) of the solder resist layer 3 and being inside the solder resist layer 3, and the portion (4c) being formed by an opening (7a) of the PET film 7 and protruding from the solder resist layer 3. Inner wall surfaces of the opening (3a) and the opening (7a) are mutually smoothly connected and thus the portions (4b, 4c) are also mutually smoothly connected and mutually continuous.

As illustrated in FIG. 2C, the intermediate metal layer 5 is formed, for example, by electroless plating on the upper surface (4d) of the metal post 4 in each opening (7a) of the PET film 7. The side surface (4a) of the metal post 4 is in close contact to the inner wall of the opening (7a) of the PET film 7. Therefore, the intermediate metal layer 5 is formed only on the upper surface (4d) among the side surface (4a) and the upper surface (4d) of the metal post 4.

The intermediate metal layer 5 is formed, for example, by first laminating the palladium layer (5a) on the upper surface (4d) of the metal post 4 and then laminating the gold layer (5b) on the palladium layer (5a). It is also possible that the palladium layer (5a) is omitted and the intermediate metal layer 5 is formed by only the gold layer (5b). As illustrated in FIG. 2D, the PET film 7 is peeled off from the solder resist layer 3, for example, by hand, and the solder resist layer 3, the portions (4c) of the side surfaces (4a) of the metal posts 4 (the portions (4c) protruding from the solder resist layer 3) and the intermediate metal layers 5 are exposed. The solder bumps 6 are respectively formed on the intermediate metal layers 5 preferably so as to not protrude from outer peripheries of the intermediate metal layers 5. The solder bumps 6 are formed by mounting solder paste on the intermediate metal layers 5, for example, by printing or the like using a mask, and applying heat to the solder paste to reflow the solder paste.

It is also possible that the solder bumps 6 are formed on the intermediate metal layers 5 before the PET film 7 is peeled off from the solder resist layer 3.

As a result, the printed wiring board of the embodiment illustrated in FIG. 1 is manufactured.

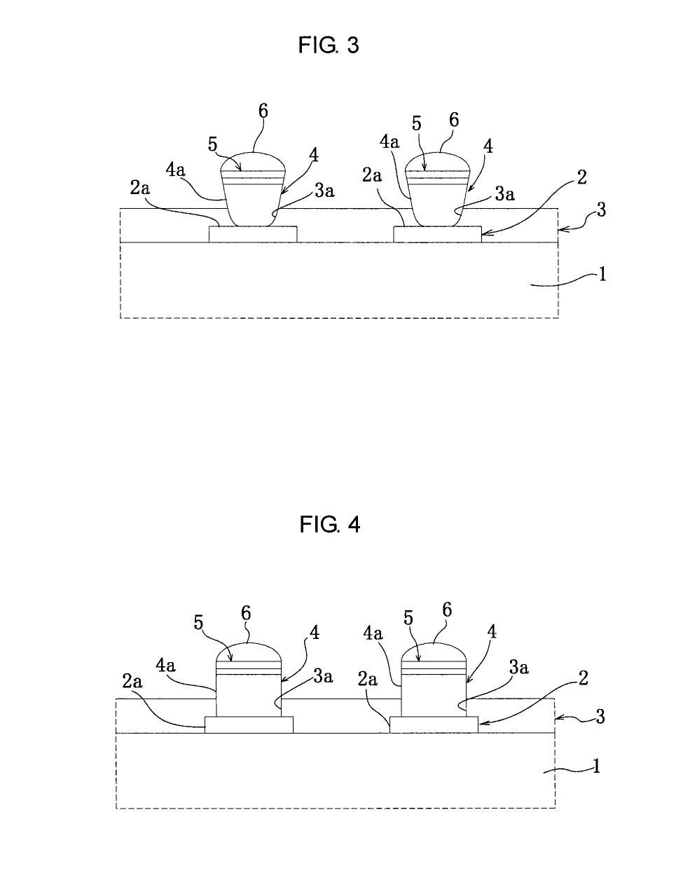

FIG. 3 is a cross-sectional view illustrating another embodiment of a printed wiring board with a metal post of the present invention. The printed wiring board of the present embodiment is different from the printed wiring board of the previous embodiment only in that the side surface (4a) of the metal post 4 is in a cup shape in which the side surface (4a) curvedly intersects the surface of the conductor pad (2a), and has the same structure as the previous embodiment in other aspects. A manufacturing method of the present embodiment for manufacturing the printed wiring board is also different from the manufacturing method of the previous embodiment only in the method for forming the openings (3a) of the solder resist layer 3 and the openings (7a) of the PET film 7, and has the same structure as the previous embodiment in other aspects.

In the embodiment illustrated in FIG. 3, when the laser output is not so high or when the thickness of the PET film 7 is large, the solder resist layer 3 is not sufficiently melted near the surface of the conductor pad (2a), and the inner wall surfaces of an opening (3a) and an opening (7a), and thus the side surface (4a) of a metal post 4 that is formed in close contact with the inner wall surfaces, form a cup shape in which the side surface (4a) curvedly intersects the surface of the conductor pad (2a).

FIG. 4 is a cross-sectional view illustrating yet another embodiment of a printed wiring board with a metal post of the present invention. The printed wiring board of the present embodiment is different from the printed wiring board of the previous embodiment only in that the side surface (4a) of the metal post 4 is in a cylindrical shape (the angle (α) is 90 degrees) in which the side surface (4a) of the metal post 4 is perpendicular to the surface of the conductor pad (2a), and has the same structure as the previous embodiment in other aspects. A manufacturing method of the present embodiment for manufacturing the printed wiring board is also different from the manufacturing method of the previous embodiment only in the method for forming the openings (3a) of the solder resist layer 3 and the openings (7a) of the PET film 7, and has the same structure as the previous embodiment in other aspects.

In the embodiment illustrated in FIG. 4, instead of laser, the openings (3a) of the solder resist layer 3 and the openings (7a) of the PET film 7 are formed by performing etching such as dry etching, plasma etching or light etching and thereafter performing an alkaline degreasing treatment. In this case, the inner wall surfaces of an opening (3a) and an opening (7a), and thus the side surface (4a) of a metal post 4 that is formed in close contact with the inner wall surfaces, are formed in a cylindrical shape (the angle (α) is 90 degrees) in which the side surface (4a) is perpendicular to the surface of the conductor pad (2a).

In the printed wiring board with metal post of the present invention, for example, for a case where a semiconductor component having solder bumps is mounted, it is also possible that the solder bumps 6 are not provided on some or all of the metal posts 4.

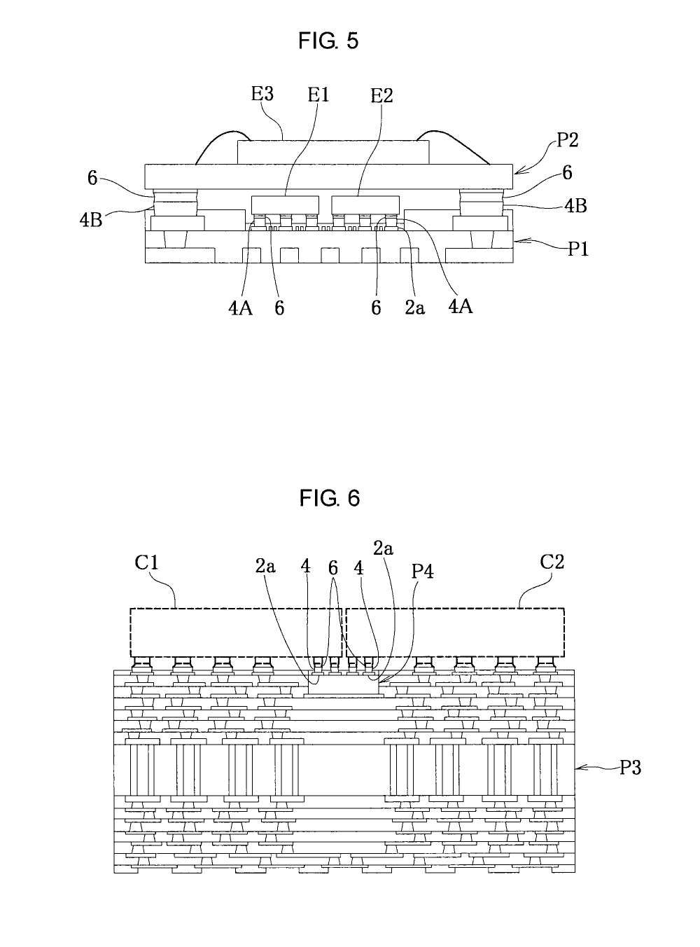

FIG. 5 is a cross-sectional view illustrating an application example of the printed wiring board with a metal post of the embodiment of the present invention. In this application example, in a printed wiring board of a package on package (POP) type in which, on a lower side package substrate (P1) (on which semiconductor components (E1, E2) are mounted), an upper side package substrate (P2) (on which a semiconductor component (E3) is mounted) is laminated and is electrically connected, the printed wiring board with a metal post of the embodiment that is manufactured in the same way as the previous embodiment is applied to the lower side package substrate (P1). The lower side package substrate (P1) is connected to terminals of the semiconductor components (E1, E2) via small-diameter metal posts (4A) (that are formed based on the present invention on conductor pads (2a) in a central region of a pitch corresponding to a fine terminal pitch of the semiconductor components (E1, E2)) and solder bumps 6 formed on the small-diameter metal posts (4A), and is connected to terminals on a lower surface of the upper side package substrate (P2) via large-diameter metal posts (4B) (that are formed based on the present invention on conductor pads (2a) in a peripheral region of a pitch corresponding to a large terminal pitch of the upper side package substrate (P2) and have a diameter and a height larger than those of the metal posts (4A)) and solder bumps 6 formed on the large-diameter metal posts (4B).

When the lower side package substrate (P1) is manufactured, it is possible that, after a solder resist layer 3 for the large-diameter metal posts (4B) and a solder resist layer 3 for the small-diameter metal posts (4A) are together covered by a PET film 7, openings (3a, 7a) of the solder resist layer 3 and the PET film 7 on the solder resist layer 3 for the large-diameter metal posts (4B), together with openings (3a, 7a) of the solder resist layer 3 and the PET film 7 on the solder resist layer 3 for the small-diameter metal posts (4A), are formed, for example, using the same UV laser, or are formed sequentially using different laser such as CO2 laser, and the metal posts (4A, 4B) are formed together or separately in the openings (3a, 7a) by electroless plating, and thereafter, the PET film 7 is peeled off. Or, it is also possible that, in a first process, the solder resist layer 3 for the small-diameter metal posts (4A) is covered by a PET film 7, the openings (3a, 7a) of the solder resist layer 3 and the PET film 7 on the solder resist layer 3 for the small-diameter metal posts (4A) are formed, for example, using UV laser, and the small-diameter metal posts (4A) are formed in the openings (3a, 7a) by electroless plating, and thereafter, in a second process, the openings (7a) of the PET film 7 on the solder resist layer 3 for the small-diameter metal posts (4A) and the solder resist layer 3 for the large-diameter metal posts (4B) are covered by another PET film 7, the openings (3a, 7a) of the solder resist layer 3 and the PET film 7 on the solder resist layer 3 for the large-diameter metal posts (4B) are formed, for example, using UV laser or different laser such as CO2 laser, or by etching or the like, and the large-diameter metal posts (4B) are formed in the openings (3a, 7a) by electroless plating, and thereafter the PET films 7 are peeled off.

FIG. 6 is a cross-sectional view illustrating another application example of the printed wiring board with a metal post of an embodiment of the present invention. In this application example, a printed wiring board (P4) with metal posts of an embodiment manufactured in the same way as in the previous embodiment is embedded in a recess that is formed in two outer layers of a multilayer printed wiring board (P3). The printed wiring board (P4) connects, via small-diameter metal posts 4 (that are formed based on the present invention on conductor pads (2a) having pitches respectively corresponding to fine terminal pitches of, for example, a memory chip (C1) and a CPU chip (C2) as semiconductor components mounted on the multilayer printed wiring board (P3)) and solder bumps 6 on the small-diameter metal posts 4, the terminals of the memory chip (C1) and the CPU chip (C2), and forms a wide band signal transmission line on/in a substrate (Wide Band Signaling on/in Substrate). It is also possible that the printed wiring board (P4) with metal posts of the embodiment is mounted on an outer layer of the two layers of the multilayer printed wiring board (P3) and connects, for example, the memory chip (C1) and the CPU chip (C2).

Terminals as connecting parts between a package substrate and a semiconductor component may be formed by mounting solder balls on conductor pads in openings of a solder resist or by printing of solder paste. However, along with demand for a fine terminal pitch, it has become difficult to reliably fill solders in openings of a solder resist.

Further, the terminals may be formed by forming solder bumps on the conductor pads in the openings of the solder resist and thus the terminals are not so high. Therefore, it is not easy for an underfill material for insulation between the terminals and for bonding of the semiconductor component to be filled in a gap between a surface of the solder resist and the semiconductor component.

A printed wiring board according to an embodiment of the present invention reliably forms conductors in openings of a solder resist and reduces variation in heights of terminals as connecting parts between a package substrate and a semiconductor component. A printed wiring board according to another embodiment of the present invention increases insulation reliability between adjacent terminals by suppressing extension of a plating conductor in a later direction. A printed wiring board according to yet another embodiment of the present invention allows an underfill material to be easily filled in a gap by increasing the height of the terminals.

A printed wiring board with a metal post according to an embodiment of the present invention includes: a resin insulating layer; a conductor layer that is formed on the resin insulating layer and includes a conductor pad; a solder resist layer that is formed on the resin insulating layer and the conductor layer and allows at least a portion of the conductor pad to exposed; and a metal post that is formed on the conductor pad. The metal post protrudes from the solder resist layer. A side surface of the metal post forms an angle with respect to a surface of the solder resist layer.

A method for manufacturing a printed wiring board with a metal post according to an embodiment of the present invention includes: preparing a printed wiring board that has a resin insulating layer and a conductor layer that is formed on the resin insulating layer and includes a conductor pad; forming a solder resist layer on the resin insulating layer and the conductor layer; affixing a resin film with a bonding layer on the solder resist layer; forming an opening that penetrates through the solder resist layer and the resin film with the bonding layer and reaches the conductor pad; forming a metal post in the opening, the metal post electrically connecting to the conductor pads; and peeling off the resin film with the bonding layer from the solder resist layer.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
a resin insulating layer;
a conductor layer formed on the resin insulating layer and comprising a plurality of conductor pads;
a solder resist layer formed on the resin insulating layer such that the solder resist layer is covering the conductor layer and has a plurality of opening portions exposing the plurality of conductor pads, respectively; and
a plurality of metal posts formed on the plurality of conductor pads such that each of the metal posts is protruding from the solder resist layer and has a side surface forming an angle with respect to a surface of the solder resist layer.

2. A printed wiring board according to claim 1, wherein each of the metal posts has the side surface such that a portion of the side surface protruding from the solder resist layer forms the angle in a range of 45 degrees to 90 degrees with respect to the surface of the solder resist layer.

3. A printed wiring board according to claim 1, wherein the plurality of metal posts comprises electroless nickel plating.

4. A printed wiring board according to claim 3, wherein the plurality of metal posts comprises the electroless nickel plating having a phosphorus content in a range of 5% to 12%.

5. A printed wiring board according to claim 1, further comprising:
an intermediate metal layer formed on the plurality of metal posts such that the intermediate metal layer is formed only on an upper surface of each of the metal posts.

6. A printed wiring board according to claim 5, wherein the intermediate metal layer comprises a palladium layer formed on the upper surface of each of the metal posts and a gold layer formed on the palladium layer.

7. A printed wiring board according to claim 1, wherein the solder resist layer has the plurality of opening portions formed such that each of the opening portions has an inner wall surface linearly intersects a surface of a respective one of the conductor pads.

8. A printed wiring board according to claim 1, wherein the solder resist layer has the plurality of opening portions formed such that each of the opening portions has an inner wall surface curvedly intersects a surface of a respective one of the conductor pads.

9. A printed wiring board according to claim 1, wherein the plurality of metal posts is formed at a pitch in a range of 30 μm to 80 μm.

10. A printed wiring board according to claim 2, wherein the plurality of metal posts comprises electroless nickel plating.

11. A printed wiring board according to claim 10, wherein the plurality of metal posts comprises the electroless nickel plating having a phosphorus content in a range of 5% to 12%.

12. A printed wiring board according to claim 2, further comprising:
an intermediate metal layer formed on the plurality of metal posts such that the intermediate metal layer is formed only on an upper surface of each of the metal posts.

13. A printed wiring board according to claim 12, wherein the intermediate metal layer comprises a palladium layer formed on the upper surface of each of the metal posts and a gold layer formed on the palladium layer.

14. A printed wiring board according to claim 2, wherein the solder resist layer has the plurality of opening portions formed such that each of the opening portions has an inner wall surface linearly intersects a surface of a respective one of the conductor pads.

15. A printed wiring board according to claim 2, wherein the solder resist layer has the plurality of opening portions formed such that each of the opening portions has an inner wall surface curvedly intersects a surface of a respective one of the conductor pads.

16. A printed wiring board according to claim 2, wherein the plurality of metal posts is formed at a pitch in a range of 30 μm to 80 μm.

17. A printed wiring board according to claim 1, wherein the plurality of metal posts is made of electroless nickel plating.

18. A method for manufacturing a printed wiring board, comprising:
preparing a printed wiring board comprising a resin insulating layer, and a conductor layer formed on the resin insulating layer and comprising a plurality of conductor pads;
forming a solder resist layer on the resin insulating layer such that the solder resist layer covers the conductor layer;
affixing a resin film having a bonding layer on the solder resist layer;
forming a plurality of opening portions penetrating through the solder resist layer and the resin film such that the plurality of opening portions reaches the plurality of conductor pads, respectively;
forming a plurality of metal posts in the plurality of opening portions respectively such that the plurality of metal posts connects to the plurality of conductor pads, respectively; and
peeling off the resin film from the solder resist layer such that each of the metal posts is protruding from the solder resist layer and has a side surface forming an angle with respect to a surface of the solder resist layer.

19. A method for manufacturing a printed wiring board according to claim 18, wherein the forming of the opening portions comprises irradiating laser upon the resin film such that the plurality of opening portions reaches the plurality of conductor pads through the solder resist layer and the resin film, respectively.

20. A method for manufacturing a printed wiring board according to claim 18, wherein the forming of the opening portions comprises etching the resin film and the solder resist layer such that the plurality of opening portions reaches the plurality of conductor pads through the solder resist layer and the resin film, respectively.
